(19) United States
(12) Patent Application Publication
(10) Pub. No.: US 2023/0079250 A1
(43) Pub. Date: Mar. 16, 2023

(54) METHOD FOR GENERATING MODEL USING VIRTUAL TARGET AND SYSTEM FOR THE SAME

(71) Applicant: Samsung Electronics Co., Ltd., Suwon-si (KR)

(72) Inventors: Ji Hye SHIN, Seoul (KR); Min Kyoung KIM, Suwon-si (KR); Jeong Min LEE, Seoul (KR); Sang Hoon MYUNG, Goyang-si (KR); Hyo Won MOON, Seoul (KR); Sung Jin KIM, Hwaseong-si (KR); Sung Duk HONG, Yongin-si (KR)

(73) Assignee: Samsung Electronics Co., Ltd., Suwon-si (KR)

(21) Appl. No.: 17/861,582

(22) Filed: Jul. 11, 2022

(30) Foreign Application Priority Data
Sep. 15, 2021 (KR) 10-2021-0123364

(51) Int. Cl. G06F 9/30; G06F 9/38

(52) U.S. Cl. CPC G06F 9/30149; G06F 9/3836

(57) ABSTRACT

A method for generating a model using a virtual target, and a system configured to generate a model using a virtual target are provided. The method for generating a model using a virtual target includes performing machine learning based on previous generation data stored in a database to generate the virtual target of a current generation, and extracting parameters related to the virtual target, and determining values of the extracted parameters based on the virtual target to generate a model.

### CROSS-REFERENCE TO RELATED APPLICATIONS

This application claims priority from Korean Patent Application No. 10-2021-0123364 filed on Sep. 15, 2021 in the Korean Intellectual Property Office, the disclosure of which is incorporated herein by reference in its entirety.

### BACKGROUND

### 1. Technical Field

The inventive concepts relate to a method for generating a model using a virtual target, and a system configured to generate a model using a virtual target.

### 2. Description of the Related Art

As the generation of semiconductor products gradually develops, process difficulty, complexity of element, and/or complexity of design for each generation increase. Incidentally, model targets of preceding products currently provided in semiconductor process design and circuit design are generated on the basis of the data measured in a limited region, and the element characteristics in a non-measured region are generated assuming that the characteristics of the predetermined or alternatively, desired or given model are followed.

Models generated on the basis of such targets are less reliable outside the measured range.

### SUMMARY

Aspects of the inventive concepts provide a solution that may predict targets in all characteristic regions for product design.

Aspects of the inventive concepts provide a method for generating a model using a virtual target capable of generating a model having improved reliability.

Aspects of the inventive concepts also provide a system configured to generate a model using a virtual target capable of generating a model having improved reliability.

However, aspects of the inventive concepts are not restricted to the one set forth herein. The above and other aspects of the inventive concepts will become more apparent to one of ordinary skill in the art to which the inventive concepts pertain by referencing the detailed description of the inventive concepts given below.

According to some aspects of the present disclosure, there is provided a method for generating a model using a virtual target includes performing machine learning based on previous generation data stored in a database to generate the virtual target of a current generation, and extracting parameters related to the virtual target, and determining values of the extracted parameters based on the virtual target to generate the model.

According to some aspects of the present disclosure, there is provided a system configured to generate a model using a virtual target includes a database, a processor, and a virtual target generator configured to generate the virtual target of a transistor using the processor, wherein the virtual target generator is configured to perform machine learning based on previous generation data stored in the database and is configured to generate a virtual target of a current generation.

According to some aspects of the present disclosure, there is provided a system configured to generate a model using a virtual target includes a storage unit which stores instructions, and a processor, wherein when the instructions are executed by the processor, the instructions cause the processor to perform machine learning based on previous generation data and generate a virtual target of a current generation, the instructions cause the processor to extract parameters related to the virtual target, and the instructions cause the processor to determine values of extracted parameters based on the virtual target and generate the model.

### BRIEF DESCRIPTION OF THE DRAWINGS

The above and other aspects and features of the inventive concepts will become more apparent by describing in detail example embodiments thereof referring to the attached drawings, in which:

FIG. 1 is a diagram which shows a system for generating a model according to some example embodiments;

FIG. 2 is a diagram showing a virtual target generator of FIG. 1;

FIG. 3 is a diagram showing the model generator of FIG. 1;

FIG. 4 is a flowchart which shows a method for generating a virtual target according to some example embodiments;

FIGS. 5 to 9 are diagrams for explaining the method for generating a virtual target according to some example embodiments; and

FIG. 10 is a flowchart which shows a method for generating a model using the virtual target according to some example embodiments.

### DETAILED DESCRIPTION OF EXAMPLE EMBODIMENTS

Hereinafter, example embodiments according to the technical idea of the inventive concepts will be described referring to the accompanying drawings.

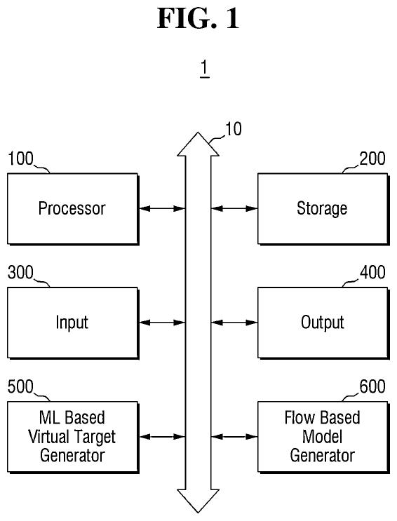

FIG. 1 is a diagram which shows a system for generating a model according to some example embodiments.

Referring to FIG. 1, a model generation system 1 may include a processor 100, a storage 200, an input unit 300, an output unit 400, a virtual target generator 500, and/or a model generator 600.

In some example embodiments, the model generation system 1 may include a computing system. For example, the model generation system 1 may be implemented as a desktop computing system, a server computing system, a clouding computing system, or the like. However, example embodiments are not limited thereto, and the model generation system 1 may be implemented as a fixed computing system, a mobile computing system, or the like.

In some example embodiments, the processor 100, the storage 200, the input unit 300, the output unit 400, the virtual target generator 500, and the model generator 600 may be connected to each other through a bus 10 to perform communication. However, example embodiments are not limited thereto, and the processor 100, the storage 200, the input unit 300, the output unit 400, the virtual target generator 500, and/or the model generator 600 may also be connected to each other, using a wired network communication, a wireless network communication or the like.

The processor 100 may control the overall operation of the model generation system 1. Further, the processor 100 may acquire information regarding user input and determine a user's requirement based on the acquired information. Further, the processor 100 may control at least a part of the constituent elements of the model generation system 1 to drive the application program stored in the storage 200. Furthermore, the processor 100 may combine and operate two or more of the constituent elements included in the model generation system 1 with each other to drive the application program.

The storage 200 may store various data required for the operation of the model generation system 1. For example, the storage 200 stores input data acquired by the input unit 300, data required for generating a virtual target in the virtual target generator 500, data required for generating a model in the model generator 600, and/or the like.

The input unit 300 may acquire various types of data. In some example embodiments, the input unit 300 may include a camera for inputting a video signal, a microphone for receiving an audio signal, a user input unit for inputting information from a user (for example, a GUI; Graphic User Interface), and/or the like. In some example embodiments, the input unit 300 may input data required for generating a virtual target in the virtual target generator 500, data required for generating the model generator 600 model, and the like in the form of a file.

The input unit 300 may acquire raw input data, and in some example embodiments, the virtual target generator 500 or the model generator 600 may perform data processing.

The output unit 400 may generate outputs related to visual sense, auditory sense, tactile sense, and/or the like.

In some example embodiments, the output unit 400 may include a display unit that outputs visual information, a speaker that outputs auditory information, a haptic module that outputs tactile information, and/or the like. The data required for the virtual target generator 500 to generate the virtual target, the data required for the model generator 600 to generate the model, and the like may be output through, for example, the display unit.

In some example embodiments, the model generation system 1 further includes a communication unit, which may transmit and receive data to and from other external electronic devices using wired and wireless communication technologies. In some example embodiments, the communication technologies used by the communication unit may include GSM (Global System for Mobile communication), CDMA (Code Division Multi Access), LTE (Long Term Evolution), 5G, WLAN (Wireless LAN), Wi-Fi (Wireless-Fidelity), Bluetooth, RFID (Radio Frequency Identification), Infrared Data Association (IrDA), ZigBee, NFC (Near Field Communication), and/or the like. However, example embodiments are not limited thereto.

The virtual target generator 500 may generate a virtual target, using the processor 100 or under the control of the processor 100.

In some example embodiments, the virtual target generator 500 may perform machine learning (ML) based on previous generation data to generate a virtual target for the current generation.

In some example embodiments, the virtual target generated by the virtual target generator 500 may be, for example, a threshold voltage target of a transistor, an off-current target of the transistor, a linear region current target of the transistor, a middle region current target of the transistor, a saturation region current target of the transistor, and a drive temperature target of the transistor. However, example embodiments are not limited thereto.

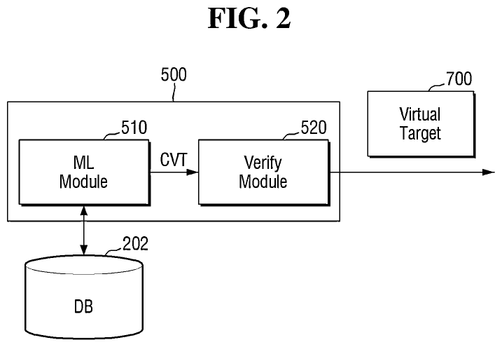

FIG. 2 is a diagram showing the virtual target generator of FIG. 1.

Referring to FIG. 2, the virtual target generator 500 may include a machine learning module 510 and/or a verification module 520.

The machine learning module 510 may perform machine learning based on the previous generation data stored in the database 202 to generate a candidate virtual target (CVT). In some example embodiments, the database 202 may be integrated and implemented with the storage described above (200 of FIG. 1). In still other example embodiments, the database 202 may be implemented separately from the storage (200 of FIG. 1) described above.

The verification module 520 performs a first verification and the second verification on the candidate virtual target (CVT) generated by the machine learning module 510, and may output the candidate virtual target (CVT) that has passed both the first verification and a second verification as the virtual target 700. A more specific explanation thereof will be described later.

Referring to FIG. 1 again, the model generator 600 may generate a model based on a virtual target (e.g., 700 of FIG. 2) generated by the virtual target generator 500, using the processor 100 or under the control of the processor 100.

In some example embodiments, the model generated by the model generator 600 may be a transistor model. Further, in some example embodiments, the model generated by the model generator 600 may be a transistor model included in an inverter which widely used in semiconductor circuit, but example embodiments are not limited thereto.

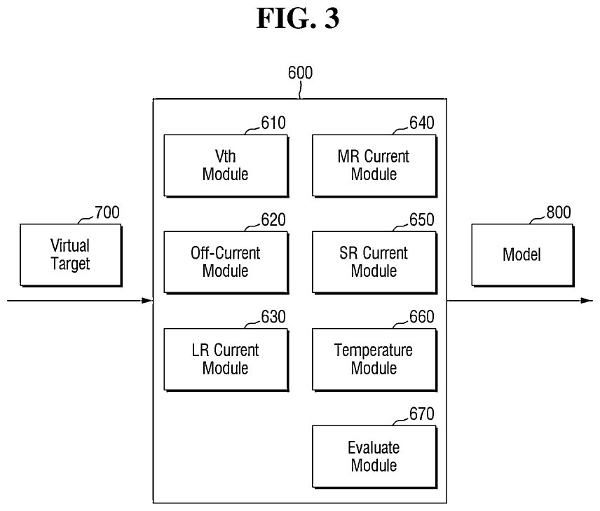

FIG. 3 is a diagram showing the model generator of FIG. 1.

Referring to FIG. 3, the model generator 600 may include a threshold voltage module 610, an off-current module 620, a linear region (LR) current module 630, a middle region (MR) current module 640, a saturation region (SR) current module 650, a drive temperature module 660, and/or an evaluation module 670. However, the configuration of the model generator 600 is not limited thereto, and modules that are not shown may be added or a part of the modules shown may be omitted as needed.

The model generator 600 may receive input of the virtual target 700 generated by the virtual target generator 500 and automatically generate a model on the basis of the flow. For example, the model generator 600 may extract parameters related to the virtual target 700 and automatically determine the values of the extracted parameters based on the virtual target to generate a model. That is, the values of the parameters extracted based on the virtual target along the flow from the threshold voltage module 610 to the evaluation module 670 may be automatically determined to generate the model 800. A specific explanation thereof will also be described below.

Referring to FIG. 1 again, in some example embodiments, at least one of the virtual target generator 500 and the model generator 600 may be implemented as software. In some example embodiments, the software may be stored in storage 200 in the form of instructions and executed by the processor 100.

Further, in some example embodiments, the virtual target generator 500 and the model generator 600 may be implemented as separate systems. For example, the virtual target generator 500 may be implemented as a first system that includes a first processor, and the model generator 600 may be implemented as a second system that includes a second processor. In some example embodiments, the virtual target generated by the virtual target generator 500 may be provided to the model generator 600 through a method such as wired communication or wireless communication.

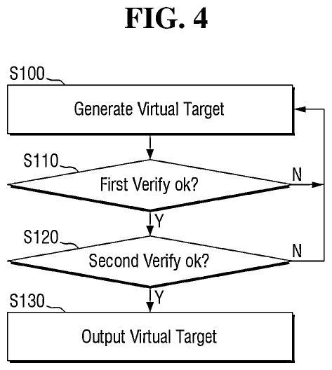

Hereinafter, a method for generating a virtual target will be described referring to FIGS. 4 to 9.

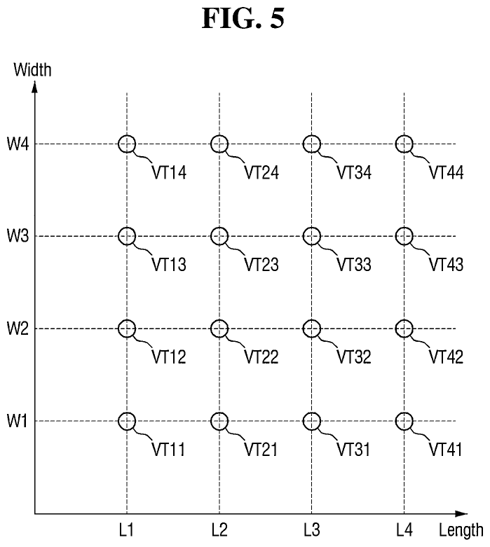

FIG. 4 is a flowchart which shows the method for generating the virtual target according to some example embodiments. FIGS. 5 to 9 are diagrams for explaining a method for generating a virtual target according to some example embodiments.

Referring to FIG. 4, the virtual target is generated (S100).

For example, referring to FIG. 2, the machine learning module 510 may perform machine learning based on the previous generation data stored in the database 202 to generate a virtual target as shown in FIG. 5. The virtual target generated at this time point may correspond to the candidate virtual target (CVT) of FIG. 2.

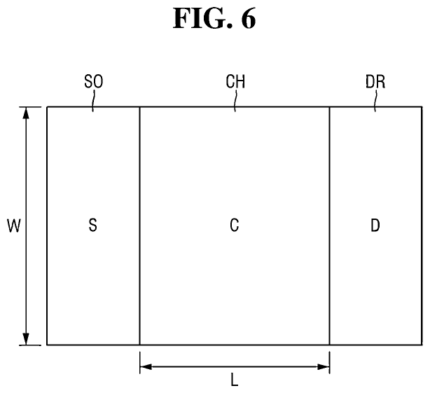

In FIG. 5, a length of an X-axis means, for example, a length L of a channel region CH between a source SO and a drain DR of the transistor shown in FIG. 6, and a width of a Y-axis means a width W of the channel region CH of the transistor shown in FIG. 6.

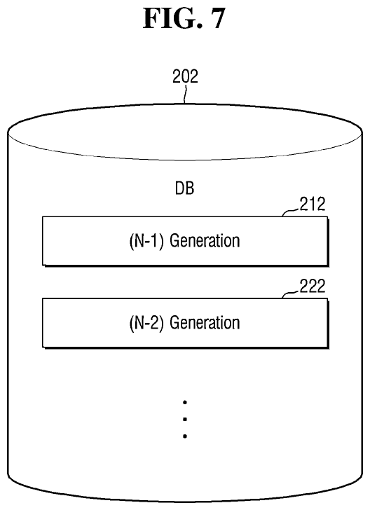

For example, if the current generation is an N (N is a natural number) generation, the database 202 stores an (N−1) generation data 212 and an (N−2) generation data 222 that are previous generations as shown in FIG. 7, and the machine learning module 510 may perform the machine learning based on the previous generation data 212 and 222 stored in the database 202 to generate the virtual target as shown in FIG. 5. Here, the previous generation data may be data for which product application has already been completed.

For example, the machine learning module 510 may perform the machine learning based on the previous generation data stored in the database 202 to generate a virtual target VT11 of the transistor in which a channel length of the current generation is L1 and a channel width is W1.

Such a virtual target VT11 may include a threshold voltage target of a transistor having a channel length of L1 and a channel width of W1, an off-current target of a transistor having the channel length of L1 and the channel width of W1, a linear region current target of a transistor having the channel length of L1 and the channel width of W1, a middle region current target of a transistor having the channel length of L1 and the channel width of W1, a saturation region current target of a transistor having the channel length of L1 and the channel width of W1, and a drive temperature target of a transistor having the channel length of L1 and the channel width of W1.

Next, the machine learning module 510 may perform machine learning based on the previous generation data stored in the database 202 to generate a virtual target VT21 of a transistor having a channel length of L2 and a channel width of W1 of the current generation.

Such a virtual target VT21 may also include a threshold voltage target of a transistor having a channel length of L2 and a channel width of W1, an off-current target of a transistor having the channel length of L2 and the channel width of W1, a linear region current target of a transistor having the channel length of L2 and the channel width of W1, a middle region current target of a transistor having the channel length of L2 and the channel width of W1, a saturation region current target of a transistor having the channel length of L2 and the channel width of W1, and a drive temperature target of a transistor having the channel length of L2 and the channel width of W1.

Next, the machine learning module 510 may perform machine learning based on the previous generation data stored in the database 202 to generate a virtual target VT12 of a transistor having a channel length of L1 and a channel width of W2 of the current generation.

Such a virtual target VT21 may also include a threshold voltage target of a transistor having a channel length of L1 and a channel width of W2, an off-current target of a transistor having the channel length of L1 and the channel width of W2, a linear region current target of a transistor having the channel length of L1 and the channel width of W2, a middle region current target of a transistor having the channel length of L1 and the channel width of W2, a saturation region current target of a transistor having the channel length of L1 and the channel width of W2, and a drive temperature target of a transistor having the channel length of L1 and the channel width of W2.

In a similar manner, the machine learning module 510 may perform machine learning based on the previous generation data stored in the database 202 to generate remaining virtual targets VT31, VT41, VT22, VT32, VT42, VT13, VT23, VT33, VT43, VT14, VT24, VT34, and VT44.

Although FIG. 5 shows an example in which the channel length is L1 to L4 and the channel width is W1 to W4 for convenience of explanation, example embodiments are not limited thereto, and the number of virtual targets may increase or decrease.

In some example embodiments, the machine learning module 510 performs machine learning based on the previous generation data stored in the database 202, and generates a virtual target corresponding to all channel lengths and all channel widths required for the current generation. Accordingly, the virtual targets corresponding to all channel lengths and all channel widths required for the current generation may be generated without rear product measurement process.

Next, referring to FIG. 4, the first verification is performed (S110).

For example, referring to FIG. 2, the verification module 520 may perform the first verification on the candidate virtual target (CVT) generated by the machine learning module 510.

The first verification is to compare the candidate virtual target (CVT) generated by the machine learning module 510 with a real target measured in the rear product.

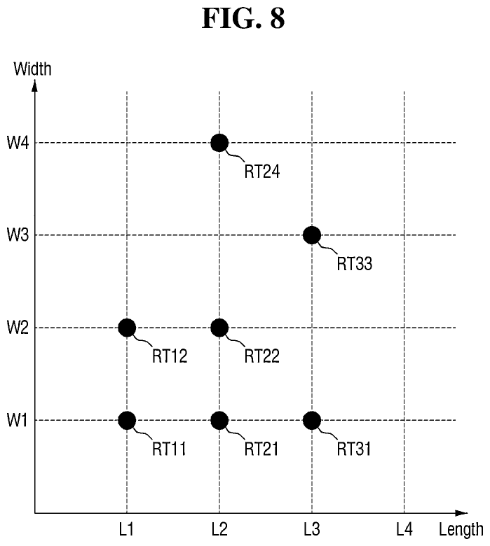

For example, as shown in FIG. 8, when there is a real target RT11 measured from the transistor having the channel length of L1 and the channel width of W1, the verification module 520 may compare the virtual target VT11 of FIG. 5 with the real target RT11 of FIG. 8. If a difference between the virtual target VT11 of FIG. 5 and the real target RT11 of FIG. 8 exceeds a predetermined or alternatively, desired or given threshold range, the verification module 520 determines this as a verification failure (S110-N).

For example, when a difference between the virtual target VT11 of the threshold voltage of the transistor having the channel length of L1 and the channel width of W1 generated by the machine learning module 510 and the real target RT11 of the threshold voltage of the transistor having the channel length of L1 and the channel width of W1 measured by the rear product exceeds a predetermined or alternatively, desired or given threshold range, the verification module 520 may determine this as a verification failure (S110-N).

Further, when a difference between the virtual target VT11 of the off-current of a transistor having the channel length of L1 and the channel width of W1 generated by the machine learning module 510 and the real target RT11 of the off-current of the transistor having the channel length of L1 and the channel width of W1 measured by the rear product exceeds a predetermined or alternatively, desired or given threshold range, the verification module 520 may also determine this as a verification failure (S110-N).

Similarly, the first verification may also be performed in the same manner on the linear region current target, the middle region current target, the saturation region current target, and/or the drive temperature target.

When such a first verification is determined to be failure (S110-N), the machine learning module 510 performs machine learning based on the previous generation data stored in the database 202 and generates the virtual target again (S100).

In contrast, when the difference between the virtual target VT11 of FIG. 5 and the real target RT11 of FIG. 8 does not exceed a predetermined or alternatively, desired or given threshold range, the verification module 520 may determine this as verification success (S110-Y). This means that the virtual target generated by the machine learning module 510 is generated in a manner similar to the real target measured from the rear product.

The real targets RT11, RT21, RT31, RT12, RT22, RT33, and RT24 shown in FIG. 8 do not exist to correspond to all channel lengths and all channel widths due to various restrictions according to the actual measurement of the product. That is, the number of virtual targets (VT31, VT41, VT12, VT22, VT32, VT42, VT13, VT23, VT33, VT43, VT14, VT24, VT34, and VT44 of FIG. 5) is larger than the number of real targets (RT11, RT21, RT31, RT12, RT22, RT33, and RT24 of FIG. 8).

The verification module 520 performs the first verification on the virtual targets (VT11, VT21, VT31, VT12, VT22, VT33V, and VT24 of FIG. 5) in which corresponding real targets (RT11, RT21, RT31, RT12, RT22, RT33, and RT24 of FIG. 8) are present, among the virtual targets (VT31, VT41, VT12, VT22, VT32, VT42, VT13, VT23, VT33, VT43, VT14, VT24, VT34, and VT44 of FIG. 5). If even one of them is determined to be a failure (S110-N), the machine learning module 510 performs machine learning based on the previous generation data stored in the database 202 and generates the virtual target again (S100).

The verification module 520 does not perform the first verification on the virtual target (e.g., VT13 of FIG. 5) in which the corresponding real target shown in FIG. 8 is not present, among the virtual targets shown in FIG. 5.

Next, referring to FIG. 4, the second verification is performed (S120).

For example, referring to FIG. 2, the verification module 520 may perform the second verification on the candidate virtual target (CVT) generated by the machine learning module 510. In some example embodiments, the second verification may be performed after the first verification is completely finished.

The second verification is to verify the trend of the candidate virtual target (CVT) generated by the machine learning module 510.

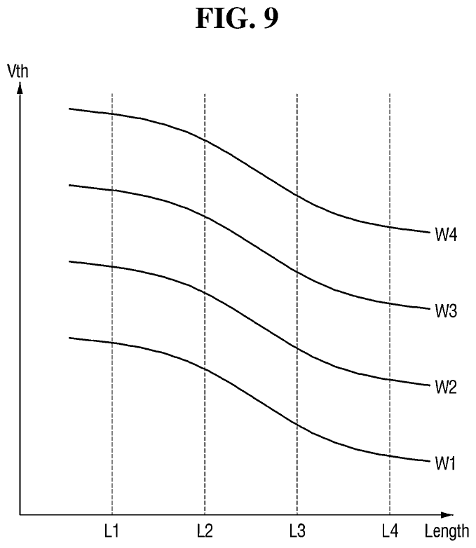

For example, the trend of the threshold voltage according to the changes in the channel length and the channel width is as shown in FIG. 9. If the virtual target generated by the machine learning module 510 is reliably generated, it is necessary to satisfy the trend as shown in FIG. 9.

For example, the threshold voltage virtual target value of the virtual target (VT14 of FIG. 5) needs to be larger than the threshold voltage virtual target value of the virtual target (VT44 of FIG. 5), and the threshold voltage virtual target value of the virtual target (VT44 of FIG. 5) needs to be larger than the threshold voltage virtual target value of the virtual target (VT43 of FIG. 5).

Incidentally, if the virtual target generated by the machine learning module 510 does not satisfy such a trend, the virtual target generated by the machine learning module 510 does not appear to be reliable. Therefore, the verification module 520 may determine this as a verification failure (S120-N). When the verification is determined to be failure in this way, the machine learning module 510 performs machine learning based on the previous generation data stored in the database 202 and generates the virtual target again (S100).

Although only the example regarding the threshold voltage target has been described in FIG. 9, the verification module 520 also performs the same trend verification on the off-current target, the linear region current target, the middle region current target, the saturation region current target, and/or the drive temperature target.

If all such trend verifications are successful, the verification module 520 may determine this as a verification success (S120-Y of FIG. 4). As a result, the virtual target for which the verification has been completed may be output (S130 of FIG. 4).

In this way, in some example embodiments, even if there is no real target corresponding to all channel lengths and all channel widths required for the current generation, it is possible to generate virtual target corresponding to all channel lengths and all channel widths required for the current generation in which the reliability is ensured. Therefore, the reliability of the model to be generated later may be improved.

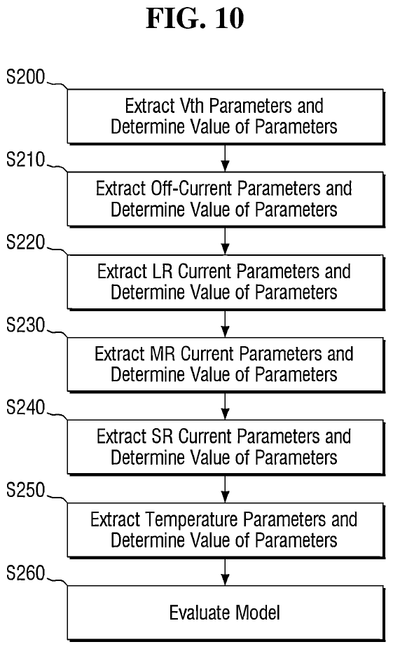

Hereinafter, a method for generating a model using the virtual target will be described referring to FIG. 10.

FIG. 10 is a flowchart which shows the method for generating the model using the virtual target according to some example embodiments.

Referring to FIG. 10, the parameters related to the threshold voltage virtual target are extracted, and the values of the extracted parameters for satisfying the threshold voltage virtual target are determined (S200).

For example, referring to FIG. 3, the threshold voltage module 610 of the model generator 600 is provided with a threshold voltage virtual target 700 and may extract parameters related to the threshold voltage virtual target 700. The threshold voltage module 610 may determine the values of the extracted parameters for satisfying the threshold voltage virtual target 700. This operation of the threshold voltage module 610 may be performed automatically.

For example, the virtual target provided to the threshold voltage module 610 is assumed to be VT11 shown in FIG. 5, and the threshold voltage target of VT11 is assumed to be 10 mV.

In some example embodiments, the threshold voltage module 610 may automatically extract parameters that affect the threshold voltage (e.g., doping concentration of the source and drain, depth of the source and drain, etc.) in a transistor having a channel length of L1 and a channel width of W1, and may automatically determine the values of the extracted parameters for satisfying 10 mV that is the threshold voltage target.

Next, the virtual target provided to the threshold voltage module 610 is assumed to be VT22 shown in FIG. 5, and the threshold voltage target of VT22 is assumed to be 20 mV.

In some example embodiments, the threshold voltage module 610 may automatically extract parameters that affect the threshold voltage (e.g., doping concentration of the source and drain, depth of the source and drain, etc.) in a transistor having a channel length of L2 and a channel width of W2, and may automatically determine the values of the extracted parameters for satisfying 20 mV which is the threshold voltage target.

The threshold voltage module 610 performs this operation for all virtual targets VT11, VT12, VT31, VT41, VT22, VT32, VT42, VT13, VT23, VT33, VT43, VT14, VT24, VT34, and VT44 shown in FIG. 5.

Next, referring to FIG. 10, the parameters related to the off-current virtual target are extracted, and the values of the extracted parameters for satisfying the off-current virtual target are determined (S210).

For example, referring to FIG. 3, the off-current module 620 of the model generator 600 is provided with the off-current virtual target 700, and may extract parameters related to the off-current virtual target 700. Further, the off-current module 620 may determine the values of the extracted parameters for satisfying the off-current virtual target 700. This operation of the off-current module 620 may also be performed automatically and may be performed in the procedure similar to the threshold voltage module 610 described above.

Next, referring to FIG. 10, parameters related to the linear region current virtual target are extracted, and the values of the extracted parameters for satisfying the linear region current virtual target are determined (S220).

For example, referring to FIG. 3, the linear region current module 630 of the model generator 600 is provided with the linear region current virtual target 700 and may extract parameters related to the linear region current virtual target 700. Further, the linear region current module 630 may determine the values of the extracted parameters for satisfying the linear region current virtual target 700. This operation of the linear region current module 630 may also be performed automatically and may be performed in the procedure similar to that described above.

Next, referring to FIG. 10, parameters related to the middle region current virtual target are extracted, and the values of the extracted parameters for satisfying the middle region current virtual target are determined (S230).

For example, referring to FIG. 3, the middle region current module 640 of the model generator 600 is provided with the middle region current virtual target 700, and may extract parameters related to the middle region current virtual target 700. Further, the middle region current module 640 may determine the values of the extracted parameters for satisfying the middle region current virtual target 700. This operation of the middle region current module 640 may also be performed automatically and may be performed in the procedure similar to that described above.

Next, referring to FIG. 10, parameters related to the saturation region current virtual target are extracted, and the values of the extracted parameters for satisfying the saturation region current virtual target are determined (S240).

For example, referring to FIG. 3, the saturation region current module 650 of the model generator 600 is provided with the saturation region current virtual target 700 and may extract parameters related to the saturation region current virtual target 700. Further, the saturation region current module 650 may determine the values of the extracted parameters for satisfying the saturation region current virtual target 700. This operation of the saturation region current module 650 may also be performed automatically and may be performed in the procedure similar to that described above.

Next, referring to FIG. 10, parameters related to the drive temperature virtual target are extracted, and the values of the extracted parameters for satisfying the drive temperature virtual target are determined (S250).

For example, referring to FIG. 3, the drive temperature module 660 of the model generator 600 is provided with the drive temperature virtual target 700 and may extract parameters related to the drive temperature virtual target 700. Further, the drive temperature module 660 may determine the values of the extracted parameters for satisfying the drive temperature virtual target 700. This operation of the drive temperature module 660 may also be performed automatically and may be performed in the procedure similar to that described above.

Next, referring to FIG. 10, the generated model is evaluated with the parameters determined via operation S200 to S250 (S260).

For example, referring to FIG. 3, the evaluation module 670 of the model generator 600 evaluates the generated model with the parameters determined through the threshold voltage module 610, the off-current module 620, the linear region current module 630, the middle region current module 640, the saturation region current module 650, and the drive temperature module 660, and may output the final model 800.

In some example embodiments, since virtual targets corresponding to all channel lengths and all channel widths required for the current generation are input, and the model is generated based on the virtual targets, the reliability of the model can be improved.

In some example embodiments, a transistor or an inverter or an integrated semiconductor circuit may be designed and/or manufactured in accordance with the model.

Any of the elements and/or functional blocks disclosed above may be connected to any other ones of the elements and/or functional blocks disclosed above. For example, there may be a one-way or a two-way communication between one element or functional block, and another element or functional block. One element or functional block may be able to send and/or receive data and/or commands to any another element and/or functional block, through a bus such as a wired and/or wireless communication bus.

Example embodiments of the ML based virtual target generator 500 and/or the flow based model generator 600 are not limited to a specific neural network. The ML based virtual target generator 500 and/or the flow based model generator 600 may include, for example, at least one of PNN (Perceptron Neural Network), CNN (Convolution Neural Network), R-CNN (Region with Convolution Neural Network), RPN (Region Proposal Network), RNN (Recurrent Neural Network), S-DNN (Stacking-based deep Neural Network), S-SDNN (State-Space Dynamic Neural Network), Deconvolution Network, DBN (Deep Belief Network), RBM (Restricted Boltzmann Machine), Fully Convolutional Network, LSTM (Long Short-Term Memory) Network, Classification Network, BNN (Bayesian Neural Network), a GRU (gated recurrent unit), a SNN (stacked neural network), a DBN (deep faith network), a GAN (generative adversarial network), an RBM (restricted Boltzmann machine), and/or the like. Additionally (and/or alternatively), the ML based virtual target generator 500 and/or the flow based model generator 600 may be trained based on at least one of various algorithms such as regression, linear and/or logistic regression, random forest, a support vector machine (SVM), and/or other types of models, such as statistical clustering, Bayesian classification, decision trees, dimensionality reduction such as principal component analysis, expert systems, and/or combinations thereof including ensembles such as random forests.

One or more of the elements disclosed above may include or be implemented in one or more processors such as hardware including logic circuits; a hardware/software combination such as a processor executing software; or a combination thereof. For example, the one or more processors more specifically may include, but are not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

In concluding the detailed description, those skilled in the art will appreciate that many variations and modifications may be made to the preferred example embodiments without substantially departing from the principles of the inventive concepts. Therefore, the disclosed preferred example embodiments of the inventive concepts are used in a generic and descriptive sense only and not for purposes of limitation.

What is claimed is:

1. A method for generating a model using a virtual target, the method comprising:
performing machine learning based on previous generation data stored in a database to generate the virtual target of a current generation; and
extracting parameters related to the virtual target, and determining values of the extracted parameters based on the virtual target to generate the model.

2. The method for generating the model using the virtual target of claim 1, wherein the virtual target includes
a first virtual target of a first transistor having a first channel length and a first channel width, and
a second virtual target of a second transistor having a second channel length different from the first channel length and the first channel width, and
the model includes a first transistor model generated on the basis of the first virtual target and a second transistor model generated on the basis of the second virtual target.

3. The method for generating the model using the virtual target of claim 2, wherein the generating the virtual target includes
a first verification operation of comparing a real target, which is measured from a third transistor having the first channel length and the first channel width, with the first virtual target.

4. The method for generating the model using the virtual target of claim 3, wherein the generating the virtual target further includes
a second verification operation of verifying a trend of the first virtual target and the second virtual target.

5. The method for generating the model using the virtual target of claim 2, wherein the virtual target further includes
a third virtual target of a third transistor which has a third channel length different from the second channel length and a second channel width different from the first channel width, and
the model further includes a third transistor model generated on the basis of the third virtual target.

6. The method for generating the model using the virtual target of claim 1, wherein the virtual target includes at least one of a threshold voltage target, an off-current target, a linear region current target, a middle region current target, a saturation region current target, and a drive temperature target of a transistor.

7. The method for generating the model using the virtual target of claim 1, wherein the generating the virtual target includes
generating all virtual targets on given channel lengths and given channel widths.

8. A system configured to generate a model using a virtual target comprising:
a database;
a processor; and
a virtual target generator configured to generate the virtual target of a transistor using the processor,
wherein the virtual target generator is configured to perform machine learning based on previous generation data stored in the database and is configured to generate a virtual target of a current generation.

9. The system configured to generate the model using the virtual target of claim 8, wherein the virtual target generator is configured to generate all virtual targets of given channel lengths of the transistor and given channel widths of the transistor.

10. The system configured to generate the model using the virtual target of claim 9, wherein the virtual target generator is configured to perform a first verification which compares at least a part of the virtual targets with a real target.

11. The system configured to generate the model using the virtual target of claim 10, wherein the virtual target generator is configured to perform a second verification which verifies a trend of the virtual targets.

12. The system configured to generate the model using the virtual target of claim 8, further comprising:
a model generator configured to generate a transistor model using the processor,
wherein the model generator is configured to receive the virtual target generated by the virtual target generator,
the model generator is configured to extract parameters related to the virtual target, and
the model generator is configured to determine the values of extracted parameters based on the virtual target and is configured to generate the transistor model.

13. The system configured to generate the model using the virtual target of claim 8, wherein the virtual target includes at least one of a threshold voltage target, an off-current target, a linear region current target, a middle region current target, a saturation region current target, and a drive temperature target of the transistor.

14. A system configured to generate a model using a virtual target, the system comprising:
a storage unit configured to store instructions; and
a processor,
wherein when the instructions are executed by the processor,
the instructions cause the processor to perform machine learning based on previous generation data and generate a virtual target of a current generation,
the instructions cause the processor to extract parameters related to the virtual target, and
the instructions cause the processor to determine values of extracted parameters based on the virtual target and generate the model.

15. The system configured to generate the model using the virtual target of claim 14, wherein the virtual target includes at least one of a threshold voltage target, an off-current target, a linear region current target, a middle region current target, a saturation region current target, and a drive temperature target of a transistor.

16. The system configured to generate the model using the virtual target of claim 14, wherein the virtual target includes
a first virtual target of a first transistor having a first channel length and a first channel width, and
a second virtual target of a second transistor having a second channel length different from the first channel length and the first channel width, and
the model includes a first transistor model generated on the basis of the first virtual target and a second transistor model generated on the basis of the second virtual target.

17. The system configured to generate the model using the virtual target of claim 16, wherein when the instructions are executed by the processor, the instructions cause the processor to perform a first verification which compares a real target measured from a third transistor having the first channel length and the first channel width with the first virtual target.

18. The system configured to generate the model using the virtual target of claim 17, wherein when the instructions are executed by the processor, the instructions cause the processor to perform a second verification which verifies a trend of the first virtual target and the second virtual target.

19. The system configured to generate the model using the virtual target of claim 16, wherein the virtual target further includes
a third virtual target of a third transistor which has a third channel length different from the second channel length and a second channel width different from the first channel width, and
the model further includes a third transistor model generated on the basis of the third virtual target.

20. The system configured to generate the model using the virtual target of claim 14, wherein when the instructions are executed by the processor, the instructions cause the processor to generate all virtual targets of given channel lengths and given channel widths.
